(19) United States
(12) Patent Application Publication
(10) Pub. No.: US 2009/0190409 A1
(43) Pub. Date: Jul. 30, 2009

(54) Integrated Circuit, Cell Arrangement, Method for Operating an Integrated Circuit and for Operating a Cell Arrangement, Memory Module

(76) Inventors: Rok Dittrich, Dresden (DE); Ulrich Klostermann, Munich (DE)

Correspondence Address: SLATER & MATSIL, L.L.P., 17950 PRESTON ROAD, SUITE 1000, DALLAS, TX, 75252, US

(21) Appl. No.: 12/021,127

(22) Filed: Jan. 28, 2008

(51) Int. Cl. G11C 11/406; G11C 16/34

(52) U.S. Cl. 365/185.25; 365/189.07; 365/222; 365/185.21

(57) ABSTRACT

An integrated circuit having a cell arrangement is provided. The cell arrangement includes at least one monitoring memory cell and at least one memory cell, wherein the at least one monitoring memory cell has a shorter retention time than the at least one memory cell. The cell arrangement further includes a detector to detect the memory status of the at least one monitoring memory cell, a comparator to compare the detected memory status of the at least one monitoring memory cell with a predefined memory status for the at least one monitoring memory cell, and a controller to control a refresh operation of the at least one memory cell dependent from the comparing result.

### TECHNICAL FIELD

Embodiments of the invention relate generally to an integrated circuit, a cell arrangement, a method for operating an integrated circuit, a method for operating a cell arrangement, and a memory module.

### BACKGROUND

The ability of a non-volatile memory to properly maintain and provide the programmed data in a period of time is represented by a parameter as “data retention”. The data retention of a memory may be affected by numerous factors, including memory device design and configuration, manufacturing process variation, operating temperature and voltage, electro-static environment, exposure to radiation, cumulative erase cycles, etc. For example, magnetic field stress (e.g., half select stress) in a thermal select magnetoresistive random access memory cell may lead to a wrongly programmed cell and thus to a loss of its original stored data. The increasing demand for large capacity and high density memory devices makes the memory cells in the memory device more easily affected by surrounding stress.

In order to maintain the programmed data in a non-volatile memory, the memory may be designed and manufactured to meet a desired specification on data retention towards stress. However, this may increase the requirement and costs on process, development and manufacturing. Another approach may be to regularly refresh the memory device such that the original programmed data is maintained. This approach, however, may increase the power consumption.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows an integrated circuit in accordance with an exemplary embodiment of the invention;

FIG. 2 shows a structure of a monitoring circuit according to one embodiment of the invention;

FIG. 3A shows an integrated circuit having a cell arrangement according to one embodiment of the invention;

FIG. 3B shows an integrated circuit having a cell arrangement according to another embodiment of the invention;

FIG. 4 shows a memory cell according to one embodiment of the invention;

FIGS. 5A and 5B show the resistance state of a multi-level MRAM cell and the drifting of the resistance state of the cell in accordance with one embodiment of the invention;

FIG. 6 shows a top view of a cell array according to an embodiment of the invention;

FIG. 7 shows a cell array structure according to another embodiment of the invention;

FIG. 8 shows the flowchart illustrating a method in accordance with one embodiment of the invention;

FIG. 9 shows the flowchart illustrating a method in accordance with another embodiment of the invention; and

FIGS. 10A and 10B show a memory module and a stackable memory module, respectively, in accordance with an embodiment of the invention.

### DETAILED DESCRIPTION OF ILLUSTRATIVE EMBODIMENTS

Generally, memory devices may be divided into two categories, volatile memory and non-volatile memory.

In the context of this description, a “volatile memory cell” may be understood as a memory cell storing data, the data being refreshed during a power supply voltage of the memory system being active, in other words, in a state of the memory system, in which it is provided with power supply voltage. Examples of volatile memory include dynamic random access memory (DRAM), static random access memory (SRAM), etc.

A “non-volatile memory cell” may be understood as a memory cell storing data even if it is not active. In an embodiment of the invention, a memory cell may be understood as being not active, e.g., if current access to the content of the memory cell is inactive. In another embodiment, a memory cell may be understood as being not active, e.g., if the power supply is inactive. Furthermore, the stored data may be refreshed on a regular timely basis, but not, as with a “volatile memory cell” every few picoseconds or nanoseconds or milliseconds, but rather in a range of hours, days, weeks or months. Alternatively, the data may not need to be refreshed at all in some designs. Examples of non-volatile memory include read only memory (ROM), flash memory, magnetoresistive random access memory (MRAM), phase change random access memory (PCRAM), conductive bridging random access memory (CBRAM), transition metal oxide random access memory (TMORAM), etc.

Embodiments of the invention provide an array of monitoring memory cells in order to detect the disturbance towards stress and time, thereby flexibly refreshing memory cells before the data loss.

An embodiment of the present invention relates to an integrated circuit having a cell arrangement, wherein the cell arrangement includes at least one monitoring memory cell and at least one memory cell. The at least one monitoring memory cell has a shorter retention time than the at least one memory cell. The cell arrangement further includes a detector to detect the memory status of the at least one monitoring memory cell, a comparator to compare the detected memory status of the at least one monitoring memory cell with a predefined memory status for the at least one monitoring memory cell, and a controller to control a refresh operation of the at least one memory cell dependent from the comparing result.

In one embodiment, the controller drives the at least one monitoring memory cell such that it has a shorter retention time than the at least one memory cell. The controller may drive the monitoring memory cell such that it receives a higher stress than the at least one memory cell, according to an embodiment of the invention. Examples of stress may include read voltage, heat voltage, magnetic field, half select stress, etc. In one embodiment, a stress produces by a voltage having inverse polarity compared with the voltage being used in a write process, which may also be referred to as a negative voltage stress, is applied to a conductive bridging random access memory (CBRAM) cell, also referred to as programmable metallization cell (PMC), written into low or high ohmic state. The voltage stress may be positive as well. In this case, intermediate states in a multilevel concept may also be stressed.

In another embodiment, the at least one monitoring memory cell is configured such that it has a shorter retention time than the at least one memory cell. The configuration of the at least one monitoring memory cell may be made with regard to memory cell parameters. Examples of memory cell parameters include shape of the memory cell, size of the memory cell, aspect ratio of a layer stack of the memory cell, and material of one layer or of a plurality of layers of the memory cell. At least one of these parameters of the monitoring memory cell may be configured such that the monitoring memory cell has a shorter retention time than the at least one memory cell. For example, the monitoring memory cell is configured to be a softer written CBRAM cell, so as to have a shorter data retention time compared with the memory cells.

The at least one monitoring memory cell or the at least one memory cell of the integrated circuit according to an embodiment of the invention is a memory cell that may suffer from a loss of the stored memory cell state. In such a case, the refresh operation would be provided for the memory cell.

The monitoring memory cell or the memory cell may be a memory cell selected from a group of different memory cell types. In an embodiment of the invention, the monitoring memory cell or the memory cell may be of a non-volatile memory cell type, for which data retention is an important parameter. Examples of the selectable memory cell types include but are not limited to magnetoresistive random access memory (MRAM) cell, Flash memory cell, and resistivity changing random access memory cell. MRAM memory cells also include a plurality of different MRAM types, including thermal select MRAM, etc., which the monitoring memory cell or the memory cell may be selected to be.

In an embodiment of the invention, a resistivity changing random access memory cell generally refers to a non-volatile memory in which the information is stored based on the resistivity of the material of the memory cell. According to one embodiment of the invention, the resistivity changing random access memory cells may be selected from a group of memory cell types consisting of solid state electrolyte random access memory cell, phase change random access memory cell, and transition metal oxide random access memory cell.

In one embodiment of the invention, the memory cell or the monitoring memory cell is selected to be solid state electrolyte random access memory cell, which is also called conductive bridging random access memory (CBRAM) cell, also referred to as programmable metallization cell (PMC). In a memory cell of this type, a vitreous or porous layer, for example, made of chalcogenide glass such as germanium-sulfide (GeS), germanium-selenide (GeSe), tungsten oxide (WOx) or copper sulfide (CuS), etc., may be situated between a metal electrode serving as an ion donor (the metal electrode may also be referred to as a reactive electrode), for example, made of Cu, Ag, Au, Zn, and a counterelectrode made of inert material, for example, W, Ti, Ta, TiN, doped Si or Pt. When a voltage or current pulse is applied between the electrodes, metal ions are driven into the chalcogenide glass by a redox reaction and form metal-enriched clusters. As a result of giving a sufficient metal concentration, a conductive bridge is formed between the two electrodes, which forms a low-resistance or “on” state of the memory cell. An electrical current or voltage pulse having opposite polarity inverts the redox reaction, so that the metal ions are drawn from the chalcogenide glass and the metal-enriched clusters are reduced. In this way, the metallically conductive bridge is terminated, and a high-resistance or “off” state of the memory cell then forms. In an embodiment of the invention, intermediate states are also possible, thereby providing more than two logical states of the memory cell.

In another embodiment, the memory cell or the monitoring memory cell is selected to be phase change RAM which uses a medium called chalcogenide, a glassy substance containing sulphur, selenium, germanium and/or tellurium. These silvery semiconductors, have the unique property that their physical state (i.e., the arrangement of their atoms) can be changed from crystalline to amorphous through the application of heat. The two or more states have very different electrical resistance properties that can be easily measured, making chalcogenide ideal for data storage.

When the monitoring memory cell or the memory cell is selected to be a Flash memory cell, the flash memory cell may be selected to be a charge storing memory cell such as, e.g., a floating gate memory cell or a charge trapping memory cell.

In one embodiment, the monitoring memory cell or the memory cell is selected to be a charge trapping memory cell, which includes a charge trapping layer structure. The charge trapping layer structure includes a dielectric layer stack including one or at least two dielectric layers being formed above one another, wherein charge carriers can be trapped in at least one of the one or at least two dielectric layers. By way of example, the charge trapping layer structure includes a charge trapping layer, which may include or consist of one or more materials being selected from a group of materials that consists of: aluminum oxide (Al₂O₃), yttrium oxide (Y₂O₃), hafnium oxide (HfO₂), lanthanum oxide (LaO₂), zirconium oxide (ZrO₂), amorphous silicon (a-Si), tantalum oxide (Ta₂O₅), titanium oxide (TiO₂), and/or an aluminate. An example for an aluminate is an alloy of the components aluminum, zirconium and oxygen (AlZrO). In one embodiment of the invention, the charge trapping layer structure includes a dielectric layer stack including three dielectric layers being formed above one another, e.g., a first oxide layer (e.g., silicon oxide), a nitride layer as charge trapping layer (e.g., silicon nitride) on the first oxide layer, and a second oxide layer (e.g., silicon oxide or aluminum oxide) on the nitride layer. This type of dielectric layer stack is also referred to as ONO layer stack. In an alternative embodiment of the invention, the charge trapping layer structure includes two, four or even more dielectric layers being formed above one another.

According to an embodiment of the invention, the at least one monitoring memory cell and the at least one memory cell included in the integrated circuit are of the same memory cell type. Accordingly, the monitoring memory cell provides an indication for the purpose of determining whether the refresh operation of the memory cell is necessary.

The integrated circuit may further include a common line coupled to the at least one monitoring memory cell and the at least one memory cell. In one embodiment, the common line is a bit line coupled to one or more monitoring memory cell and memory cell. In another embodiment, the common line is a word line.

In one embodiment, the at least one monitoring memory cell and the at least one memory cell are multi-level memory cells. Multi-level memory cell refers to the ability of a single memory cell to store or represent more than a single bit of data. A multi-level memory cell may store 2, 4, 8 . . . etc. bits in a single storage location. For example, the multi-level memory cells are configured to store a plurality of bits by showing distinguishable threshold voltages dependent on the amount of electric charge stored in the memory cell, thereby representing a plurality of logic states. In an embodiment, not every memory level needs to be detected and compared. For example, only a subgroup of memory levels which are particularly critical to degradation may be chosen to be monitored in order to determine whether a refresh operation is necessary. In this context, it should be mentioned that in general, a multi-level memory cell may be provided also based on any other of the before mentioned memory cell types, wherein the distinguishable threshold voltages may be provided in accordance with the respectively used technology.

In another embodiment, the at least one monitoring memory cell and the at least one memory cell are multi-bit memory cells. Multi-bit memory cell is intended to include memory cells which are configured to store a plurality of bits by spatially separated electric charge storage regions, for example, thereby representing a plurality of logical states.

Another embodiment of the invention relates to a cell arrangement, which includes at least one monitoring memory cell and at least one memory cell. The at least one monitoring memory cell may have a shorter retention time than the at least one memory cell. The cell arrangement further includes a detector to detect the memory status of the at least one monitoring memory cell, a comparator to compare the detected memory status of the at least one monitoring memory cell with a predefined memory status for the at least one monitoring memory cell, and a controller to control a refresh operation of the at least one memory cell dependent from the comparing result.

A further embodiment of the invention relates to a method for operating an integrated circuit having a cell arrangement. The memory status of at least one monitoring memory cell of the cell arrangement is detected, wherein the at least one monitoring memory cell has a shorter retention time than at least one memory cell of the cell arrangement which is assigned to the at least one monitoring memory cell. The detected memory status of the at least one monitoring memory cell is compared with a predefined memory status for the at least one monitoring memory cell, and the at least one memory cell is refreshed dependent from the comparing result.

In one embodiment, the at least one monitoring memory cell is driven such that it has a shorter retention time than the at least one memory cell. The monitoring memory cell may be driven to receive a higher stress than the memory cell, such that the reference memory cell has a shorter retention time than the memory cell.

In another embodiment, the at least one monitoring memory cell is configured such that it has a shorter retention time than the at least one memory cell. The configuration may be made with regard to at least one memory cell parameter selected from a group of memory cell parameters, which consists of the shape of a memory cell, size of a memory cell, aspect ratio of a layer stack of a memory cell, and material of one layer or of a plurality of layers of a memory cell.

The at least one monitoring memory cell or the at least one memory cell of the integrated circuit may be of a memory cell that suffers from a loss of the stored memory cell state, such that detection of the memory status and the refreshing of the memory cell might be necessary.

The monitoring memory cell or the at least one memory cell may be selected from a group of memory cell types, such as magnetoresistive random access memory cell, flash memory cell, or resistivity changing random access memory cell.

A resistivity changing random access memory cell may be of a memory cell type selected from a group of memory cell types, such as solid state electrolyte random access memory cell, phase change random access memory cell and transition metal oxide random access memory cell. The monitoring memory cell or the memory cell may be selected to be any of these memory cell types.

In another embodiment when the monitoring memory cell or the memory cell is selected to be a flash memory cell, which can be of a floating gate memory cell type or a charge trapping memory cell type.

The at least one monitoring memory cell and the at least one memory cell may be selected to be of the same memory cell type, such that the monitoring memory cell may provide an indication for the purpose of determining whether the memory cell is to be refreshed.

In one embodiment, the at least one monitoring memory cell and the at least one memory cell are multi-level memory cells, wherein a single cell may store or represent more than a single bit of data. In another embodiment, the at least one monitoring memory cell and the at least one memory cell are multi-bit memory cells, which are configured to store a plurality of bits by spatially separated electric charge storage regions, for example.

Another embodiment of the present invention relates to a method for operating a cell arrangement. The memory status of at least one monitoring memory cell of the cell arrangement is detected, wherein the at least one monitoring memory cell has a shorter retention time than at least one memory cell of the cell arrangement which is assigned to the at least one monitoring memory cell. The detected memory status of the at least one monitoring memory cell is compared with a predefined memory status for the at least one monitoring memory cell, and the at least one memory cell is refreshed dependent from the comparing result.

A further embodiment of the invention relates to a memory module including a plurality of integrated circuits, wherein at least one integrated circuit of the plurality of integrated circuits includes a cell arrangement. The cell arrangement includes at least one monitoring memory cell and at least one memory cell, wherein the at least one monitoring memory cell has a shorter retention time than the at least one memory cell. The cell arrangement also includes a detector to detect the memory status of the at least one monitoring memory cell, a comparator to compare the detected memory status of the at least one monitoring memory cell with a predefined memory status for the at least one monitoring memory cell, and a controller to control a refresh operation of the at least one memory cell dependent from the comparing result.

The memory module may be a stackable memory module in which at least some of the integrated circuits are stacked one above the other.

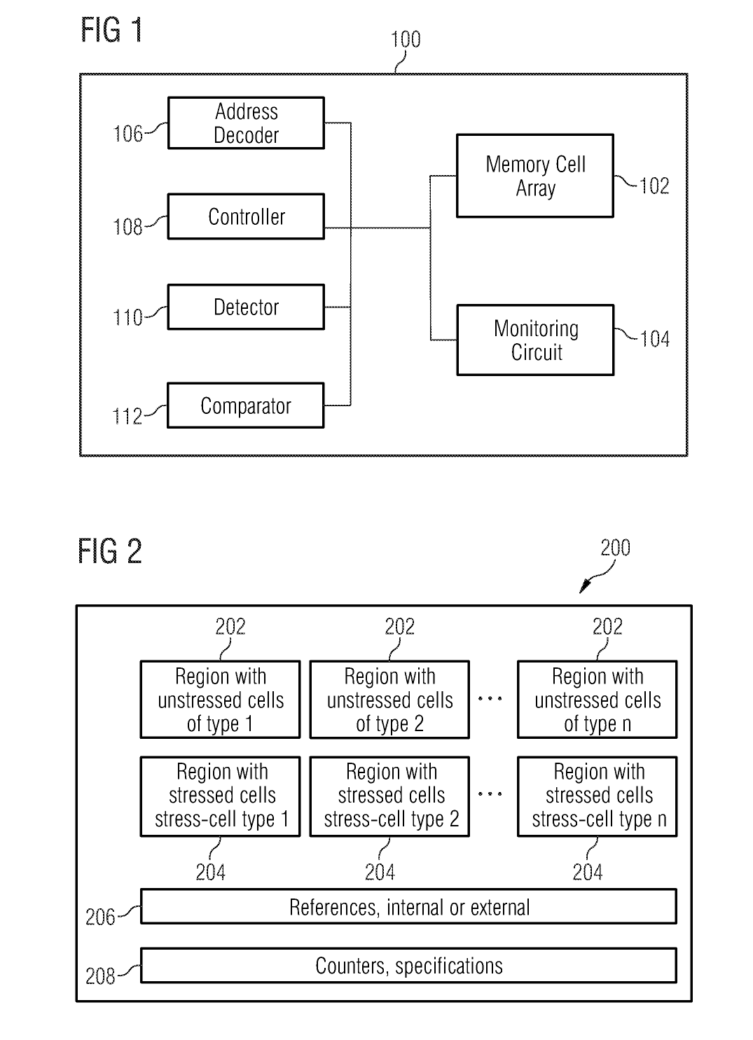

FIG. 1 illustrates an integrated circuit in accordance with an exemplary embodiment of the invention.

In an embodiment of the invention, the integrated circuit includes a cell arrangement 100, which includes resistance memory cells and peripheral devices. According to an embodiment of the invention, the cell arrangement 100 has a memory cell array 102 which includes at least one memory cell, wherein the memory cells may be arranged in rows and columns in a matrix form. The cell arrangement 100 further includes a monitoring circuit 104. At least one monitoring memory cell may be provided in the monitoring circuit 104, wherein the at least one monitoring memory cell is designed and manufactured such that it has a shorter data retention time than the memory cell in the memory cell array 102. The monitoring memory cells may also be arranged in a matrix form, similar to the arrangement of the memory cells. In an embodiment of the invention, the at least one monitoring memory cell may be selected to be of the same type as the memory cell(s), for example, thermal select magnetoresistive memory cells, such that the monitoring memory cell provides a good indication of whether the memory cell needs to be refreshed. It should be mentioned that the memory cells in the memory cell array 102 and the monitoring memory cells in the monitoring circuit 104 may be arranged in a different way than in a matrix form, for example in a zig-zag architecture. The structure of the monitor unit 104 will be illustrated with regard to FIG. 2 later on.

In addition to the memory cell array 102 and the monitoring circuit 104, the integrated circuit may include an address decoder 106, which receives a logical address of a memory cell to be selected, for example, a memory cell to be programmed, read or erased or a monitoring memory cell to be read or refreshed, and maps the logical address of the memory cell to the actual physical address of the memory cell to be selected within the memory cell array 102 or the monitoring circuit 104. Furthermore, the address decoder 106 provides the select signal to the control lines, to which the memory cell to be selected is connected to such that the desired memory cell is selected.

A detector 110 is provided, the detector 110 being, in one embodiment of the invention, formed by one or a plurality of sense amplifiers (for example, one or more current amplifier(s) or one or more voltage amplifier(s)) which are used to sense the current flowing through a selected monitoring memory cell within the monitoring circuit 104 to determine the memory status of the selected monitoring memory cell. The cell arrangement 100 of the integrated circuit also includes a comparator 112 to compare the determined memory status with a predefined memory status of the monitoring memory cell which is, for example, stored in an internal memory of the monitoring circuit 104. The compared result can be used to determine whether the data stored in the monitoring memory cell(s) is maintained or lost, so as to determine whether a refresh operation is necessary.

Furthermore, a controller 108, for example, a microprocessor, in an alternative embodiment of the invention implemented as hard wired logic, is provided. The controller 108 provides voltage signals in order to provide the required voltages and currents in order to perform the respectively selected operation on the selected memory cell within the memory cell array 102 or the selected monitoring memory cell within the monitor unit 104. By way of example, the controller 108 provides a sequence of voltages and currents to a selected memory cell in order, for example, to align the magnetization of the selected memory cell. In another example, the controller 108 provides control signals to refresh the memory cells in the memory cell array 102, when the comparator 112 indicates an inconsistency of the determined memory status of a monitoring memory cell with its predefined memory status. The refresh operation may be controlled by the controller 108 to perform on all the memory cells in the memory cell array 102, or on some memory cells to which the detected monitoring memory cell(s) is assigned.

FIG. 2 shows a detailed structure 200 of the monitoring circuit 104 in accordance with one embodiment of the invention. The monitoring circuit 104 may include one or more monitoring memory cells, which may be divided into several regions. For example, first regions 202 represent regions with unstressed monitoring memory cells, which tend to lose data after a period of time not for the reasons of external stress, but rather due to the design and the specification of the monitoring memory cell. Different specification of the monitoring memory cells may exist in different size, shape, aspect ratio, material of layer(s), pinning strength and direction of the pinning layer, etc. There may be a plurality of first regions 202 with unstressed monitoring memory cells, each of which having unstressed monitoring memory cells of one type. As an example, region with unstressed monitoring memory cells of a first type 1 may include thermal-select magnetoresistive monitoring memory cells of a smaller size, region with unstressed monitoring memory cells of a second type 2 may include thermal-select magnetoresistive monitoring memory cells of a larger size, and so on. It is also possible for regions of unstressed monitoring memory cells to include different species of monitoring memory cells, for example, a region with unstressed monitoring memory cells of type x may include Flash monitoring memory cells. These monitoring memory cells are designed to be more sensitive than the monitoring memory cells which are used to store data, meaning that the monitoring memory cells have shorter data retention time than the monitoring memory cells.

The monitoring circuit 104 may also include second regions 204 representing regions with stressed monitoring memory cells, which tend to lose data due to external stress in operating the integrated circuit. Examples of external stress may include but are not limited to half select stress, read voltages, heat voltages, magnetic fields, etc. The second regions 204 with stressed monitoring memory cells may be of different types.

Some regions may be subject to different types of stress, for example, different voltage and/or temperature. Other regions may be different types of memory cells under the same types of stress. In an illustrative example, region of a first type 1 and region of a second type 2 may include magnetoresistive monitoring memory cells with identical specifications subject to a high voltage supply and to a low voltage supply, respectively. Region of a third type 3 and region of a fourth type 4 may include magnetoresistive monitoring memory cells with different sizes but subject to the same stress. Moreover, the types of stress can be correlated with the operation of the dedicated array area to be controlled, e.g., half select stress can be correlated to the write operation frequency.

In an embodiment of the invention, the monitoring circuit 104 further includes references 206, whether internal or external to the monitor circuit 104, to provide the predefined memory status of the respective monitoring memory cell. In an embodiment of the invention, a counter 208 is also provided to maintain the information of the specifications of the respective monitoring memory cell. As an alternative embodiment, the functionality of the counter 208 may also be achieved using a hard-wired logic, wherein the hard-wired logic includes a write operation resulting in resets the monitoring memory cells into their initial states. Thus, the counter 208 may illustratively be replaced by the hard-wired logic.

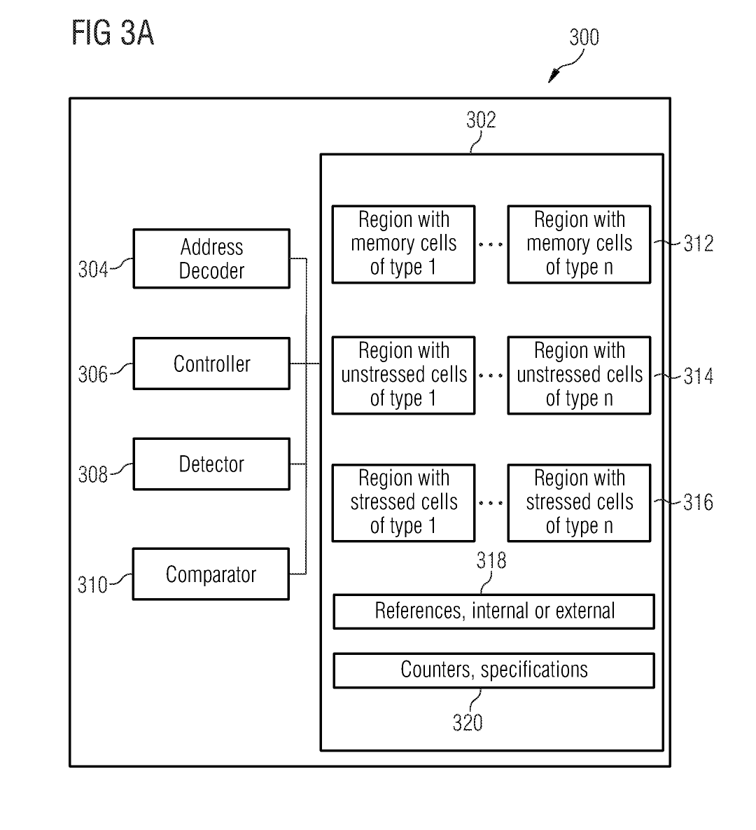

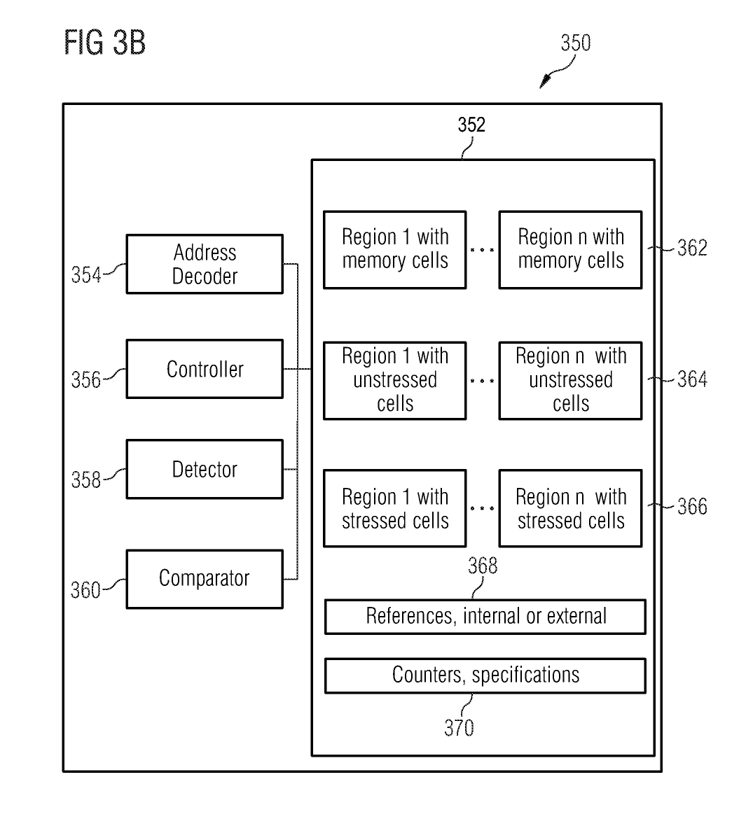

FIG. 3A shows another embodiment of the invention, wherein the monitoring circuit is, instead of being a separate circuit from the memory array, integrated into the memory array.

The cell arrangement 300 is similar to the cell arrangement 100 in FIG. 1, which also includes an address decoder 304, a controller 306, a detector 308 and a comparator 310. The difference is in an embodiment that the memory cell array 102 and the monitoring circuit 104 of FIG. 1 are integrated as a single cell array 302 in FIG. 3A. Specifically, the cell array 302 includes memory cells of different types 1, 2, . . . n, for each type a respective region 312 being assigned. In accordance with the division of the regions 312 for the memory cells, the unstressed monitoring memory cells of types 1, 2, . . . n are divided into n first regions 314, such that each first region 314 with unstressed monitoring memory cells is assigned to a corresponding region with memory cells 312. Similarly, the cell array 302 further includes stressed monitoring memory cells of types 1, 2, . . . n divided into n second regions 316. These second regions 316 may include different types of monitoring memory cells under different types of stress or under the same type of stress. In other examples, the second regions 316 may also include the same types of cells under different types of stress or under the same type of stress.

By having the first regions 314 and the second regions 316, the intrinsic properties of the memory cells is used to design an analog sensor, which automatically inhibits sensitivity towards exposure to stress and time without the need to power on the memory chip. The monitoring circuit in accordance with an embodiment of the invention thus acts as a powerless sensor. Moreover, the monitoring circuit in accordance with an embodiment of the invention may have a lower complexity compared with using a Error Correction Code (ECC) control.

The cell array 302 further may include references 318 to provide predefined memory status of the respective reference cell of the first regions 314 and the second regions 316. These reference values may be stored in internal or external memory cells, for example. In other examples, the cell array 302 includes other group of cells which serves as reference cells for cells in regions 312 or 314 or 316 in order to determine the memory status of those cells in those regions. Furthermore, the cell array 302 may include a counter 320 to maintain the information of the specifications of the respective monitoring memory cell, e.g., information of the different types of cells and different types of stress.

FIG. 3B shows an integrated circuit including a cell arrangement 350 according to an embodiment of the invention.

Similar to FIG. 3A, the cell arrangement 350 includes an address decoder 354, a controller 356, a detector 358 and a comparator 360. The cell array 352 in the cell arrangement 350 includes regions with memory cells 362, regions with unstressed cells 364 and regions with stressed cells 366. In this embodiment, the memory cells and the monitoring memory cells are of the same memory cell type, e.g., MRAM cells. The monitoring memory cells may be designed to have a shorter data retention time than the memory cells.

An illustrative example is provided in the following with regard to FIG. 3B. A first region 1 with memory cells 362 includes magnetoresistive memory cells used to store the data or information. The first region 1 with unstressed cells 364 includes magnetoresistive memory cells not subject to any stress, and assigned to the first region 1 with memory cells 362. These unstressed cells may be magnetoresistive memory cells designed, e.g., with a higher sensitivity than those of the first region 362 to have a shorter data retention. Thus, a refresh operation may be performed on the memory cells of Region 362 before any loss of data stored therein. At the same time, the first region 1 with stressed cells 366 includes magnetoresistive memory cells subject to stress, and assigned to the first region 1 with memory cells 362. The stressed cells may be subject to higher stress than the memory cells used to store data in the first region 362. One example of stress is half select stress when adjacent cells on the same bit line or word line are written in an MRAM array. The reference cells may be arranged with the memory cells in a predetermined pattern, e.g., coupled to the same word line or bit line. Thus, when the adjacent memory cell on the same word line or bit line is programmed, the half select stress is generated automatically on the reference cell, thereby saving power consumption compared with separately generating the half select stress when the reference cell and the memory cell are not coupled to the same word line or bit line.

The cell array 352 also stores the references values, either internally or externally, for the reference cells of the regions 364 and 366, representing the predefined memory status of the respective reference cell. The cell array 352 includes other group of cells which serves as reference cells for cells in regions 362 or 364 or 366 in order to determine the memory status of those cells in those regions. Furthermore, the cell array 352 may include a counter 370 to maintain the information of the specifications of the respective monitoring memory cell, e.g., information of the different types of cells and different types of stress.

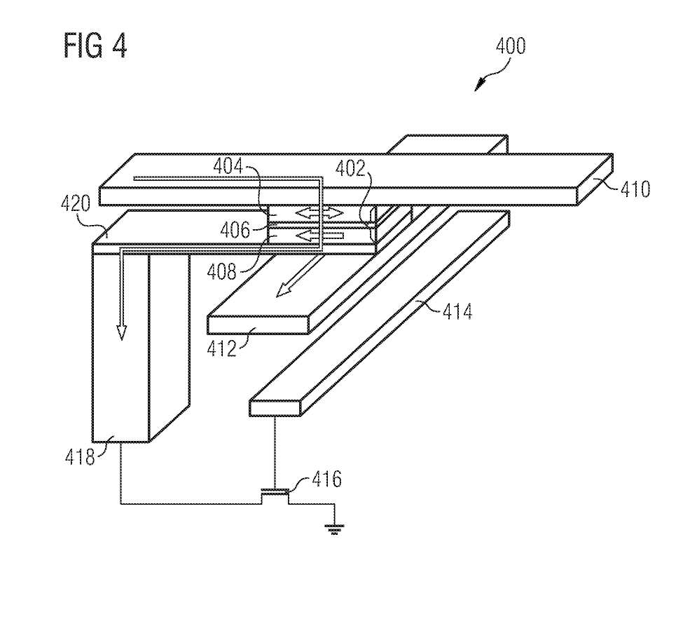

FIG. 4 shows one example of the memory cell 400 or the monitoring memory cell 400 according to one embodiment of the invention. The memory cell or the reference cell is selected to be the magnetoresistive memory cell in the 1T1MTJ (one transistor, one magnetic tunnel junction) structure. In an embodiment of the invention, the MTJ stack 402 includes a storage layer 404, a tunnel barrier layer 406 and a reference layer 408. The storage layer 404 has a switchable magnetic orientation, while the reference layer 408 has a fixed magnetic orientation.

A bit line 410 is coupled to the MTJ stack 402 next to its storage layer 404. A word line 412 and a control line 414, arranged parallel to each other while perpendicular to the bit line 410, are coupled to the MTJ stack 402 next to the reference layer 408 side of the MTJ 402 without direct contact. The word line 412 and the control line 414 may be parallel to each other in a vertical direction as an example shown in FIG. 4, or may be parallel to each other in a horizontal direction depending on the design of the cell structure. The control line 414 is connected to the gate of a transistor 416 to activate the MTJ 402 for reading and writing operation. The drain of the transistor 416 is connected to the reference layer 408 of the MTJ through a conductive structure 418 and an interconnect layer 420. The conductive structure 418 may be a single conductive layer, or may include various vias, interconnects and additional conductive structures. The source of the transistor 416 is grounded. It is to be noted that various types of transistors may be used depending on the design of the circuit, wherein the connected component of the source, drain and gate of the transistors will be changed correspondingly.

For example in the context of thermal select magnetoresistive memory cell, the storage layer 404 and the reference layer 408 may each include multiple layers, including a pinning layer structure. The pinning layer structure of the storage layer 404 may have a lower blocking temperature than the pinning layer structure of the reference layer 408. The control line 414 switches on the transistor 416, and the current is provided by the bit line 410 to heat the memory cell to be programmed. Furthermore, current with a particular direction flowing through the word line 412 generates a magnetic field, which switches the magnetization orientation of the storage layer 404. The thermal switching of the thermal select magnetoresistive memory cells allows to program a plurality of memory cells concurrently. However, the thermal select magnetoresistive memory cell may suffer from slow creep away of the programmed memory status due to exposure to stress and time.

In an embodiment of the invention, the programmed memory status of a magnetoresistive memory cell is read by determining the resistance of the magnetoresistive memory cell.

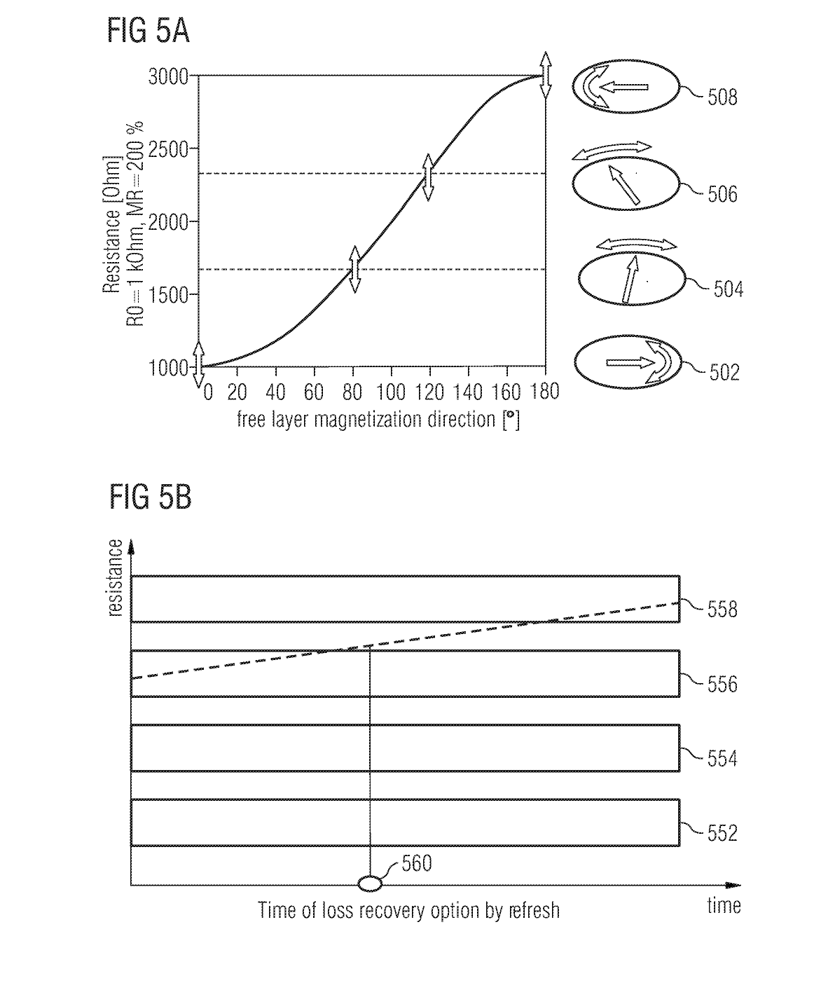

FIG. 5A illustrates the resistance state of a multi-level thermal select MRAM, wherein the magnetization orientation corresponding to 4 resistance states 502-508 are shown. For example, a first resistance state 502 represent a first logical value “00”, a second resistance state 504 represent a second logical value “01”, a third resistance state 506 represent a third logical value “10” and a fourth resistance state 508 represent a fourth logical value “11”. Furthermore, the magnetization orientation of the MRAM may be lost due to time and stress, such as temperature, cross talk, half select stress or read voltage stress, thus losing its original data or cause erroneous data. For example, if the resistance drift from the second resistance state 504 to the third resistance state 506 due to time and stress, the original data of the second logical value “01” will be changed to the third logical value “10”, and will then cause an error.

FIG. 5B shows the drift of resistance state of the four state thermal select MRAM of FIG. 5A. The four resistance states represent logical values “00”, “01”, “10”, “11”, respectively. The four bands 552-558 shown in FIG. 5B represent the read margin for each resistance band representing the four resistance states, respectively. As shown in FIG. 5B, the resistance state “10” creeps away towards resistance state “11”. As a conceptual illustration, the data loss may be prevented if the refresh operation is performed before the time point 560. After the time point 560, the original data cannot be recovered. Therefore, it is necessary to refresh the memory cells in appropriate time, which is determined by a monitor unit with monitoring memory cells as explained above according to an embodiment of the invention.

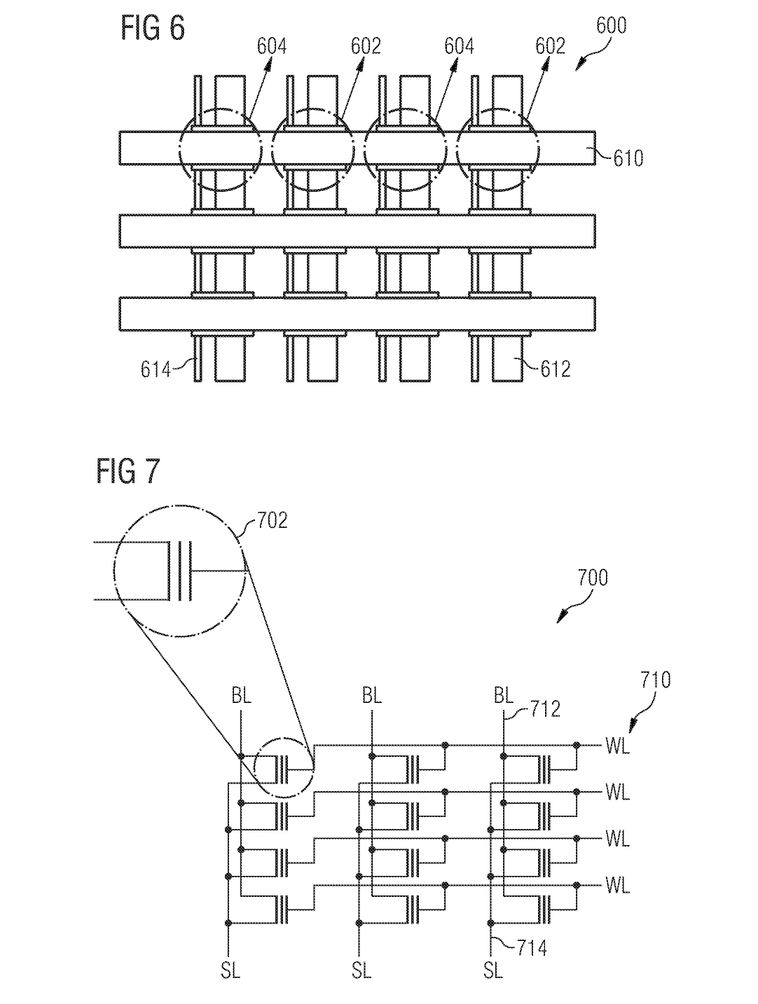

FIG. 6 is a top view of a cell array 600 according to FIG. 3B wherein the memory cells and the reference cells are selected to be the magnetoresistive memory cells of FIG. 4.

The memory cells 602 and the corresponding stressed reference cells 604 are coupled to a bit line 610, such that some types of stress may be generated automatically as explained above. It is also possible to arrange the memory cells 602 and the reference stressed cells 604 to be coupled to a word line 612 in another example. In this example, there is a reference cell 604 assigned to each memory cell 602. In other examples, one reference cell 604 may be assigned to a plurality of memory cells 602, such as the memory cells 602 coupled to the same bit lines. The reference unstressed cells may be arranged separate from the memory cells 602 and the reference stressed cells 604 in order to avoid the disturbance of stress. The cells are placed at the intersection of the bit lines 610 and word lines 612, with the control lines 614 extending parallel to the word lines 612. The order of the bit lines 610, word lines 612 and control lines 614 may be different in different circuit designs such that the bit lines 610 are arranged below the cells, and the word lines 612 and control lines 614 are arranged above the cells.

In another embodiment when the memory cells and the reference cells are flash memory cells, a NOR array architecture 700 is shown in FIG. 7.

In the NOR array architecture 700, the flash memory cells 702 are arranged in a matrix. The gates of each flash memory cell 702 are coupled by rows to word lines (WL) 710, and the drains are coupled by columns to bit lines (BL) 712. The source of each flash memory cell is coupled to a common source line (SL) 714. The NOR architecture flash memory array 700 is accessed, e.g., by a decoder, to activate a plurality of flash memory cells by selecting the word line 710 coupled to their gates. The selected flash memory cells coupled to the selected word line 710 then place the stored data on the respective bit lines 712 by flowing a differing current from the source lines 714 to the bit lines 712. It is understood that the flash memory cell and the reference flash memory cell may be arranged to be coupled to the same word line or the same bit line, such that some kind of stress may be automatically generated on the reference flash memory cell as illustrated above. Furthermore, the cell array of FIG. 7 may also be designed in a NAND flash memory architecture in another embodiment.

FIG. 8 shows a method for operating an integrated circuit having a cell arrangement according to one embodiment of the invention.

In 802, the memory status of at least one monitoring memory cells in the cell arrangement is detected. The detected memory status is then compared with a predefined memory status of the monitoring memory cell in 804. The predefined memory status may be stored in an internal or external memory of the cell arrangement, for example. Depending on the compared result, it is determined in 806 whether to refresh at least one memory cell, to which the monitoring memory cell is assigned. For example, if the compared result shows that the detected memory status is not consistent with the predefined memory status of the monitoring memory cell, the memory cell is refreshed. Optionally, the monitoring memory cell may also be refreshed.

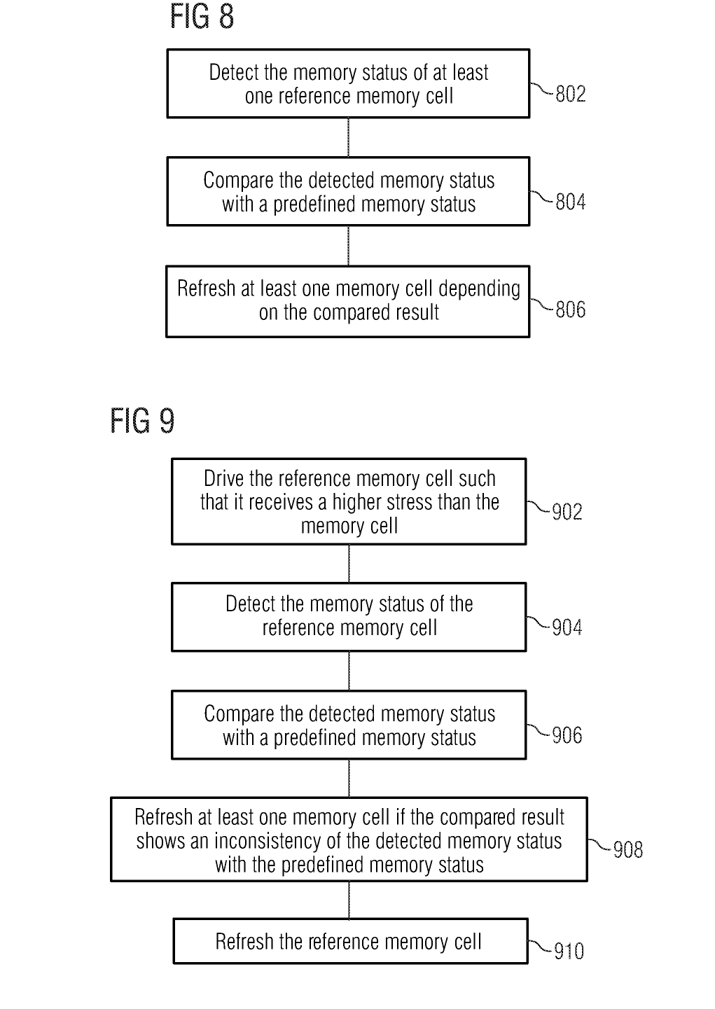

FIG. 9 shows a method of operating an integrated circuit having a cell arrangement according to another embodiment of the invention. In 902, the reference cell of the cell arrangement is driven, for example, by a controller in the integrated circuit, such that a higher stress is received by the monitoring memory cell, compared to the stress received by the memory cell of the cell arrangement. The memory status of the monitoring memory cell is then detected in 904, and compared with a predefined memory status of the monitoring memory cell in 906. If the compared result shows an inconsistency of the detected memory status with the predefined memory status, the memory cell of the cell arrangement is refreshed in 908. The monitoring memory cell is also refreshed in 910. The refresh of the memory cell and of the monitoring memory cell may be performed concurrently or separately.

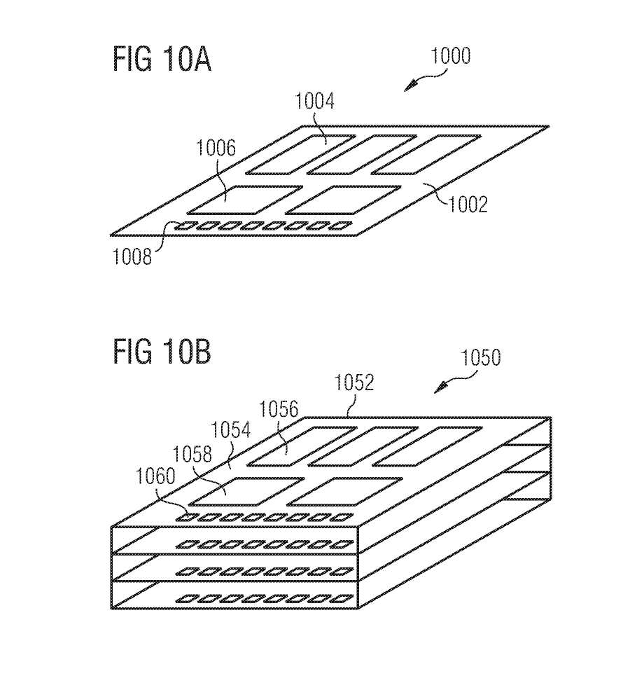

As shown in FIGS. 10A and 10B, in some embodiments, memory devices such as those described herein may be used in modules. In FIG. 10A, a memory module 1000 is shown, on which one or more memory device having memory cell arrays 1004 are arranged on a substrate 1002. The memory cell arrays 1004 may include numerous memory cells, e.g., the memory cells and the monitoring memory cells arranged in a predefined pattern in accordance with an embodiment of the invention. The monitoring memory cell is selected to have a shorter retention time than the memory cell. The memory module 1000 may also include one or more electronic devices 1006, which may include memory, processing circuitry, control circuitry, addressing circuitry, detecting circuitry, comparing circuitry, bus interconnection circuitry, or other circuitry or electronic devices that may be combined on a module with a memory device, such as the memory device 1004. Additionally, the memory module 1000 includes multiple electrical connections 1008, which may be used to connect the memory module 1000 to other electronic components, including other modules.

As shown in FIG. 10B, in some embodiments, these modules may be stackable, to form a stack 1050. For example, a stackable memory module 1052 may contain one or more memory devices having memory cell arrays 1056, arranged on a stackable substrate 1054. The memory cell arrays 1056 contains memory cells and monitoring memory cells in accordance with an embodiment of the invention. The stackable memory module 1052 may also include one or more electronic devices 1058, which may include memory, processing circuitry, control circuitry, addressing circuitry, detecting circuitry, comparing circuitry, bus interconnection circuitry, or other circuitry or electronic devices that may be combined on a module with a memory device, such as the memory device 1056. Electrical connections 1060 are used to connect the stackable memory module 1052 with other modules in the stack 1050, or with other electronic devices. Other modules in the stack 1050 may include additional stackable memory modules, similar to the stackable memory module 1052 described above, or other types of stackable modules, such as stackable processing modules, control modules, communication modules, or other modules containing electronic components.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. An integrated circuit comprising:
at least one memory cell;
at least one monitoring memory cell, wherein the at least one monitoring memory cell has a shorter retention time than the at least one memory cell;
a detector to detect a memory status of the at least one monitoring memory cell;
a comparator to compare the detected memory status of the at least one monitoring memory cell with a predefined memory status for the at least one monitoring memory cell; and
a controller to control a refresh operation of the at least one memory cell dependent on a comparison result from the comparator.

2. The integrated circuit of claim 1, wherein the controller is configured to control a refresh operation of the at least one monitoring memory cell dependent on the comparison result.

3. The integrated circuit of claim 1, wherein the controller drives the at least one monitoring memory cell such that it has a shorter retention time than the at least one memory cell.

4. The integrated circuit of claim 3, wherein the controller drives the at least one monitoring memory cell such that it receives a higher stress than the at least one memory cell.

5. The integrated circuit of claim 1, wherein the at least one monitoring memory cell is configured such that it has a shorter retention time than the at least one memory cell with regard to at least one memory cell parameter selected from the group of memory cell parameters consisting of:
shape of a memory cell;
size of a memory cell;
aspect ratio of a layer stack of a memory cell; and
material of one or more layers of a memory cell.

6. The integrated circuit of claim 1, wherein the at least one monitoring memory cell or the at least one memory cell is of a memory cell that suffers from a loss of a stored memory cell state.

7. The integrated circuit of claim 1, wherein the at least one monitoring memory cell or the at least one memory cell comprises a memory cell type selected from the group consisting of:
magnetoresistive random access memory cell;
flash memory cell; and
resistivity changing random access memory cell.

8. The integrated circuit of claim 1, wherein the at least one monitoring memory cell and the at least one memory cell are of a same memory cell type.

9. The integrated circuit of claim 1, further comprising a common line coupled to the at least one monitoring memory cell and the at least one memory cell.

10. The integrated circuit of claim 1, wherein the at least one monitoring memory cell and the at least one memory cell are multi-level memory cells.

11. The integrated circuit of claim 1, wherein the at least one monitoring memory cell and the at least one memory cell are multi-bit memory cells.

12. A method for operating an integrated circuit, the method comprising:
detecting a memory status of a monitoring memory cell, wherein the monitoring memory cell has a shorter retention time than a memory cell assigned thereto;
comparing the detected memory status of the monitoring memory cell with a predefined memory status for the monitoring memory cell; and
refreshing the memory cell dependent on a result of the comparing.

13. The method of claim 12, further comprising refreshing the monitoring memory cell dependent on the result of the comparing.

14. The method of claim 12, further comprising driving the monitoring memory cell such that it receives a higher stress than the memory cell.

15. The method of claim 12, wherein the monitoring memory cell is configured such that it has a shorter retention time than the memory cell.

16. The method of claim 15, wherein the monitoring memory cell is configured such that it has a shorter retention time than the memory cell with regard to at least one memory cell parameter, the memory cell parameter being selected from the group of memory cell parameters consisting of:
shape of a memory cell;
size of a memory cell;
aspect ratio of a layer stack of a memory cell; and
material of one layer or of a plurality of layers of a memory cell.

17. The method of claim 12, wherein the monitoring memory cell or the memory cell comprises a memory cell that suffers from a loss of a stored memory cell state.

18. The method of claim 12, wherein the monitoring memory cell or the memory cell is of a memory cell type selected from the group of memory cell types consisting of:
magnetoresistive random access memory cell;
flash memory cell; and
resistivity changing random access memory cell.

19. The method of claim 12, wherein the monitoring memory cell and the memory cell are of a same memory cell type.

20. The method of claim 12, wherein the monitoring memory cell and the memory cell comprise multi-level memory cells.

21. The method of claim 12, wherein the monitoring memory cell and the memory cell comprise multi-bit memory cells.

22. A method for operating a cell arrangement, the method comprising:
detecting a memory status of at least one monitoring memory cell, wherein the at least one monitoring memory cell has a shorter retention time than at least one memory cell assigned thereto;
comparing the detected memory status of the at least one monitoring memory cell with a predefined memory status for the at least one monitoring memory cell; and
refreshing the at least one memory cell dependent on a result of the comparing.

23. A memory module, comprising:
a plurality of integrated circuits, wherein at least one integrated circuit of the plurality of integrated circuits comprises a cell arrangement, the cell arrangement comprising:
at least one memory cell;
at least one monitoring memory cell, wherein the at least one monitoring memory cell has a shorter retention time than the at least one memory cell;
a detector to detect a memory status of the at least one monitoring memory cell;
a comparator to compare the detected memory status of the at least one monitoring memory cell with a predefined memory status for the at least one monitoring memory cell; and
a controller to control a refresh operation of the at least one memory cell dependent on a result of the comparing.
